(19) United States
(12) Patent Application Publication
(10) Pub. No.: US 2022/0316047 A1
(43) Pub. Date: Oct. 6, 2022

(54) EVAPORATION SOURCE FOR VACUUM EVAPORATION APPARATUS

(71) Applicant: ULVAC, INC., Kanagawa (JP)

(72) Inventor: Shuuji Saitou, Kanagawa (JP)

(73) Assignee: ULVAC, INC., Kanagawa (JP)

(21) Appl. No.: 17/764,866

(22) PCT Filed: Jun. 4, 2020
(86) PCT No.: PCT/JP2020/022080

§ 371 Date: Mar. 29, 2022

(30) Foreign Application Priority Data
Oct. 4, 2019 (JP) 2019-184125

(51) Int. Cl. C23C 14/24

(52) U.S. Cl. CPC C23C 14/243

(57) ABSTRACT

The evaporation source for use in the vacuum evaporation apparatus in vacuum evaporation of a film formation object inside a vacuum chamber has: a main cylindrical body having a crucible part to be filled with an evaporation material Em; a secondary cylindrical body protruded from such a portion of the main cylindrical body as is positioned above the evaporation material; and a heater capable of heating the evaporation material that is filled in the crucible part. The secondary cylindrical body is detachably mountable on the main cylindrical body while shifting a phase of the discharge opening. A lid body is disposed in a manner to open or close an upper-surface opening of the crucible part. In a state in which the upper-surface opening of the crucible part is blocked by the lid body in a vacuum atmosphere, the evaporation material in the crucible part is heated by the heater.

### TECHNICAL FIELD

The present invention relates to an evaporation source for a vacuum evaporation apparatus in which vacuum evaporation is performed on an object on which a thin film is evaporated inside a vacuum chamber (this “object” is hereinafter called “film formation object”).

### BACKGROUND ART

A sheet-shaped substrate made, e.g., of resin has a flexibility and good workability is known to be fabricated into electronic parts and optical parts by forming, on one surface or on both surfaces thereof, a predetermined single layer or multi-layer thin films of predetermined metallic films, oxide films, and the like in the vacuum atmosphere, or otherwise by performing etching or heat treatment. As a vacuum processing apparatus for performing a film forming processing like this kind of vacuum processing is known in Patent Document 1. This vacuum processing apparatus is provided with a vacuum chamber in which vacuum atmosphere can be formed therein. This vacuum chamber has therein: feed rollers for feeding a sheet-shaped substrate; take-up rollers for taking up the substrate on which a film has been formed; and guide rollers for transporting the sheet-shaped substrate that has been feed out of the feed rollers. At the bottom surface of the vacuum chamber, there is provided an evaporation source in a manner to lie opposite to such a portion of the sheet-shaped substrate as is horizontally transported between a pair of guide rollers.

The evaporation source is provided with a container box of parallelepiped for containing therein an evaporation material. In such a portion of the container box as lies opposite to the surface of the sheet-shaped substrate (i.e., the upper surface in the vertical direction), there is provided a slit-shaped discharge opening (so-called “line source”). Then, after having filled the container box with the evaporation material, the evaporation material in the container box is heated by a heating means in the vacuum atmosphere so as to sublime or vaporize the evaporation material. This sublimated or vaporized evaporation material is allowed to be discharged out of the discharge opening due to pressure difference as compared with the inside of the vacuum chamber so as to get adhered to, and deposited on, a portion of the sheet-shaped substrate so that a predetermined thin film is evaporated (so-called deposition-up type of film formation).

By the way, in case the similar thin film is formed on each of both sides of the sheet-shaped substrate (so-called dual-surface film formation), the above-mentioned conventional example cannot be utilized for the so-called deposition-down type of film formation from the structural limitations thereof (in other words, the evaporation direction relative to the film formation object cannot substantially be changed). Therefore, in an attempt to perform film formation on both the surfaces, thin film formation will have to be performed on one of the surfaces of the sheet-shaped substrate while the sheet-shaped substrate is being horizontally transferred between a pair of guide rollers above the evaporation source. Thereafter, the substrate is turned upside down and once again the sheet-shaped substrate is transferred above the evaporation source, thereby performing film formation on the opposite surface. As a result, there will be needed a mechanism for converting the upside and the downside of the sheet-shaped substrate, and additional transfer rollers will be needed. This solution will therefore bring about a more complicated vacuum evaporation apparatus and an increase in cost.

### PRIOR ART DOCUMENTS

### Patent Documents

### Patent Document 1: Japanese Patent No. 5543159

### SUMMARY OF THE INVENTION

### Problems that the Invention is to Solve

This invention has been made in view of the above-mentioned point and has a problem of providing an evaporation source for a vacuum evaporation apparatus in which the evaporation direction relative to the film formation object can be arbitrarily set with a flexibility

### Means for Solving the Problems

In order to solve the above-mentioned problem, this invention is an evaporation source for a vacuum evaporation apparatus which performs vacuum evaporation on a film formation object in a vacuum chamber. The evaporation source comprises: a main cylindrical body disposed in a posture in which a longitudinal direction thereof coincides with a vertical direction, the main cylindrical body having a crucible part to be filled with an evaporation material; a secondary cylindrical body protruded from such a part of the main cylindrical body as is positioned above the evaporation material filled in the crucible part, the secondary cylindrical body having a discharge opening; and a heating means capable of heating at least the evaporation material that is filled in the crucible part. The secondary cylindrical body is detachably mountable on the main cylindrical body while shifting a phase of the discharge opening. A lid body is disposed to block an upper-surface opening of the crucible in a manner to open or close the opening. The evaporation source is arranged: that, in a state in which the upper-surface opening of the crucible part is blocked by the lid body in a vacuum atmosphere, the evaporation material in the crucible part is heated by the heating means so as to sublime or vaporize the evaporation material; and that, when the lid body is left open, the sublimated or vaporized evaporation material is transferred to the secondary cylindrical body while maintaining a vapor pressure thereof.

According to this invention, the secondary cylindrical body is mounted on the main cylindrical body depending on the direction (evaporation direction) in which the evaporation material is going to be supplied toward the film formation object, for example, in a posture in which the discharge opening faces vertically upward direction, in a posture in which the discharge opening faces a horizontal direction, or in a posture in which the discharge opening faces vertically downward direction. Then, in a state in which the lid body is left open in the atmosphere, the evaporation material to be selected depending on the thin film that is going to be formed on the film formation material, is charged into the crucible part from the vertically upper direction thereof. Once the crucible part has been charged with the evaporation material, the upper-surface opening of the crucible part is blocked by the lid body. The heating means is then operated in the vacuum atmosphere to thereby heat the evaporation material in the crucible part.

It is to be noted here that, in case the evaporation material is volatile in nature, the evaporation material in the crucible part will be liquefied when it reaches a predetermined temperature. The evaporation material charged in the crucible part will start evaporation from the upper-layer portion according to the vapor pressure curve peculiar to the evaporation material. At this time, the pressure in the crucible part (partial pressure of the evaporation material) will rise to the vapor pressure that corresponds to the predetermined temperature, and will then be transitioned to a thermal equilibrium state in which evaporation will be restrained by vapor pressure rate-limitation. At least an upper-layer part of the evaporation material that is charged in the crucible part will be completely liquefied (at this time, if the heating means is made up of a heat generating body such as a sheath heater, the output of the heater will be stabilized at a stage of reaching the thermal equilibrium state). When the lid body is left open in this state, the vaporized evaporation material will be transferred (diffused) into the secondary cylindrical body while maintaining the vapor pressure so that the difference in partial pressure relative to the secondary cylindrical body that is present in the vacuum atmosphere attains an equilibrium state, and will then be discharged out of the discharge opening into the vacuum atmosphere.

In this manner, according to this invention, an arrangement has been made in which the evaporation source is divided into: the portion (main cylindrical body) in which the evaporation material is heated for sublimation or evaporation; and the portion (secondary cylindrical body) in which the sublimated or vaporized evaporation material is transferred and discharged (i.e., the evaporation source is arranged to be of a gas-displacement system), and a further arrangement has been made in which the phase of the discharge opening that is disposed in the secondary cylindrical body can be shifted. Therefore, the evaporation direction relative to the film formation object can be arbitrarily set such as a so-called “depo-up system” (up-evaporation system) or a “depo-down system” (down-evaporation system), thereby bringing about a flexible system. In addition, an arrangement has been employed in which the upper-surface opening of the crucible part can be opened or closed by the lid body. Therefore, under conditions in which the inner atmosphere of the main cylindrical body and the secondary cylindrical body cannot maintain an equilibrium state in the crucible part, the lid body can be refrained from allowing to be opened, whereby the evaporation material can be prevented from getting accumulated on the inside of the main cylindrical body and the secondary cylindrical body. As a result, the vapor pressure can be controlled only by the heating means for heating the crucible part.

Now, for example, in case the film formation object is a sheet-shaped substrate having a predetermined width, the discharge opening is ordinarily constituted by a slit-shaped arrangement which is elongated in one direction. But if the evaporation material that has been transferred from the main cylindrical body into the secondary cylindrical body is allowed to be discharged out of the discharge opening in an ununiform manner, a film of a uniform film thickness distribution in the width direction cannot be formed on the film formation object that lies opposite to the discharge opening. On this occasion, when the evaporation material changes in kind, the distribution of the evaporation material that is discharged out of the discharge opening will also change. Therefore, it is necessary to construct the evaporation source so that the evaporation material can be discharged with good uniformity through the slit-shaped discharge opening. In this invention, preferably, a distribution plate is disposed by insertion into the secondary cylindrical body, the distribution plate having formed therethrough distribution holes for introducing, into the discharge opening, the sublimated or vaporized evaporation material transferred into the secondary cylindrical body. According to this arrangement, by appropriately setting the shape, opening areas, and the like of the distribution holes to be formed in the distribution plate, the evaporation material can be discharged out of the slit-shaped discharge opening with good uniformity. Further, should the evaporation material change, e.g., in kind, replacement may be made with another distribution plate having a different shape of the distribution holes and opening areas, thereby bringing about superior flexibility.

In this invention, the heating means preferably further comprises a heat generating body like a sheath heater disposed in the secondary cylindrical body. According to this arrangement, since the heat generating body (heat generating source) is present in the secondary cylindrical body, as compared with the above-mentioned heat transfer system through the wall surface of the secondary cylindrical body, not only can the arrangement be industrially advantageous constitution with an improved thermal efficiency, but also can the adhering (deposition) of the evaporation material transferred to the secondary cylindrical body be positively prevented (so-called self cleaning), due to the fact that the inner wall of the secondary cylindrical body is heated to a temperature above the sublimation temperature or the evaporation temperature of the evaporation material. Still furthermore, the evaporation pressure of the evaporation material in the main cylindrical body and the secondary cylindrical body can advantageously be stabilized.

### BRIEF DESCRIPTION OF THE DRAWINGS

FIG. 1 is a sectional view, as seen from the front, of a vacuum processing apparatus provided with an evaporation source according to an embodiment of this invention.

FIG. 2 is a sectional view taken along the line II-II in FIG. 1.

FIG. 3 (a) is a sectional view showing in enlargement the evaporation source according to this embodiment, and FIG. 3 (b) is a sectional view taken along the line IIIb-IIIb in FIG. 3 (a).

FIG. 4 is a plan view showing in enlargement the evaporation source.

FIG. 5 is a sectional view showing a state in which the evaporation source has been taken out of the vacuum processing chamber.

### MODE FOR CARRYING OUT THE INVENTION

Hereinbelow, with reference to the FIGURES, the film formation object is defined to be a sheet-shaped substrate Sw. A description will then be made of an embodiment of an evaporation source for a vacuum evaporation apparatus of this invention with reference to an example in which films are formed on both surfaces of the sheet-shaped substrate Sw while the sheet-shaped substrate Sw is traveling in a vacuum atmosphere. In the following, an assumption is made that, in a posture in which the axial direction of a can roller coincides with the horizontal posture, the can roller is contained inside the vacuum chamber Vc. An axial direction is defined as an X-axis direction, and the direction perpendicular to the X-axis on the same horizontal plane is defined as Y-axis direction, and a vertical direction perpendicular to the X-axis and the Y-axis is defined to be a Z-axis direction. The direction such as up and down shall be based on the posture of installation of the vacuum evaporation apparatus.

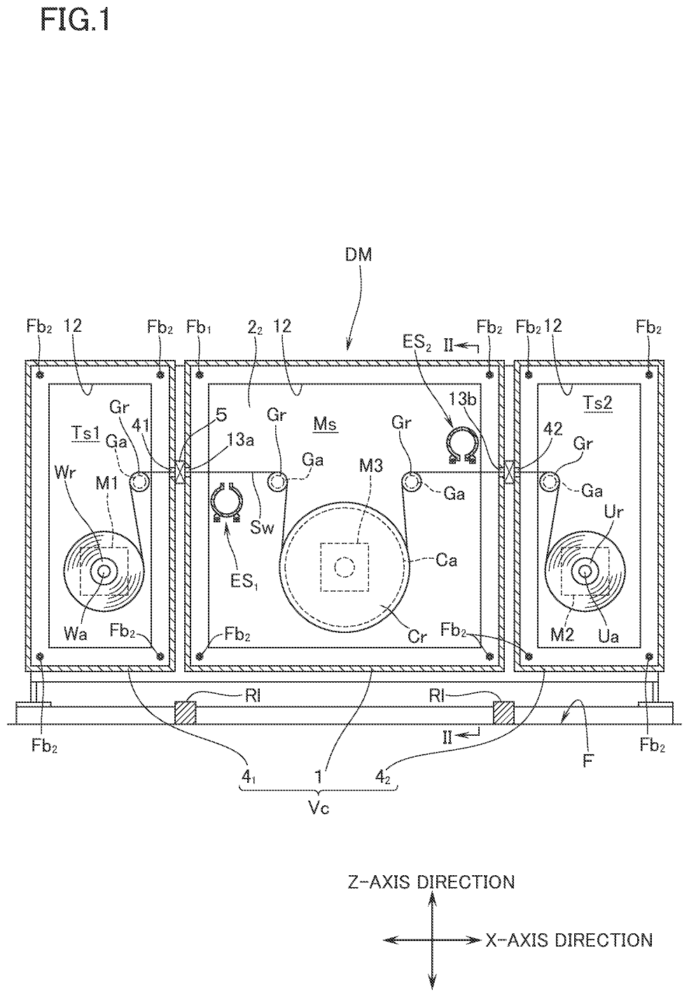

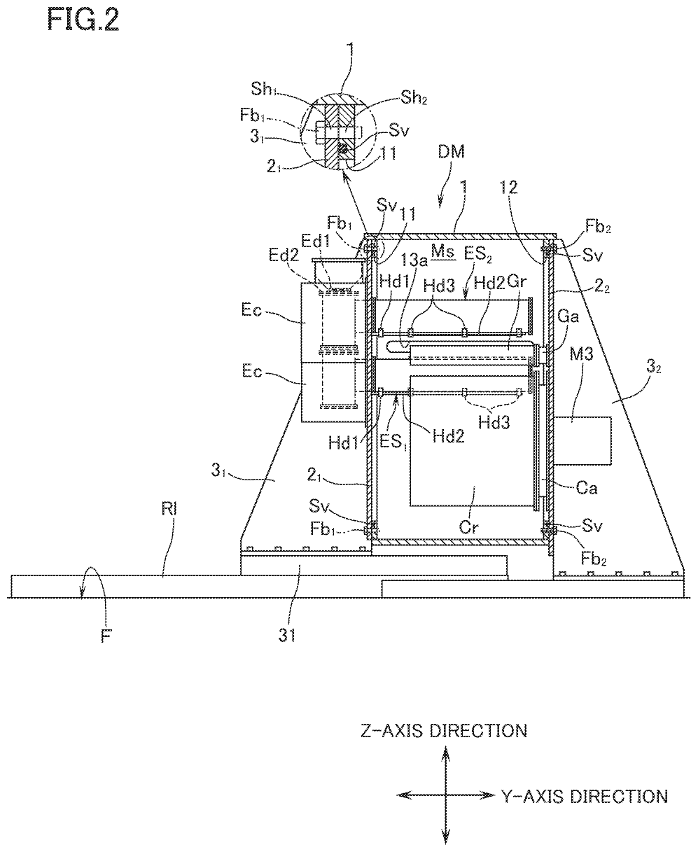

With reference to FIGS. 1 and 2, a vacuum processing apparatus DM provided with evaporation sources ES₁, ES₂ according to this embodiment has a central vacuum processing chamber Ms, and a vacuum chamber Vc respectively having the first and the second transfer chambers Ts1, Ts2. Although not particularly illustrated, the central processing chamber Ms and each of the transfer chambers Ts1, Ts2 have connected thereto a vacuum pump unit which is constituted by a turbo molecular pump, a rotary pump, etc. so that a vacuum atmosphere can be formed therein. The vacuum processing chamber Ms has a profile of rectangular parallelopiped and is defined by: a first chamber part 1, as a chamber main body, which has opposing side wall surfaces in the Y-axis direction respectively left open; first and second supporting plates 2₁, 2₂ as partition walls respectively covering an opening 11, 12 of the first chamber part 1, in a hermetically sealed manner, through vacuum seals Sv such as O-rings and the like; and an extension chamber Ec which will be described later. In this case, in predetermined positions on the upper surface and the lower surface of the first and the second supporting plates 2₁, 2₂, first screw threads Sh₁ penetrating in the Y-axis direction are bored. When the first and the second supporting plates 2₁, 2₂ are mounted in the openings 11, 12 of the first chamber part 1, the wall surface part of the first chamber part 1 corresponding to the first threaded hole Sh₁ has formed a second threaded hole Sh₂. Then, in a state in which the first and the second supporting plates 2₁, 2₂ have been mounted in the openings 11, 12 of the first chamber part 1, each of the first and the second threaded holes Sh₁, Sh₂ are connected to the tightening bolts Fb₁, Fb₂ of each threaded holes, it is so arranged that the vacuum seal Sv can fix in position the wall surface portions positioned around the openings 11, 12 of the first chamber part 1, and the first and the second support plates 2₁, 2₂ in a state tightly pressed to each other.

On the sides, facing away from each other, of the first and the second supporting plates 2₁, 2₂, there are respectively disposed first and second supporting frames 3₁, 3₂ such that a posture of the first and the second supporting plates 2₁, 2₂ erected in the Z-axis direction can be maintained. On the lower surface of the first supporting frame 3₁ there is disposed a slider 31 that moves in a slidable manner along rail members R1 laid on the floor surface F. The slider 31 is thus arranged to be moveable between a withdrawal position which is away in one Y-axis direction (left side in FIG. 2) from the opening 11 in the first chamber part 1 and a hermetically sealed position which closes the opening 11 of the first chamber part 1 (see FIG. 2). On both sides in the X-axis direction of the first chamber part 1, contours in the shape of rectangular parallelepiped are secured so that second chamber parts 4₁, 4₂ as chamber main bodies having openings on the other side surfaces in the Y-axis direction are respectively disposed in communication with each other. Each of the transfer chambers Ts1, Ts2 is defined by the second chamber parts 4₁, 4₂ and the first and the second supporting plates 2₁, 2₂. In this case, although not particularly described by illustration, at predetermined positions on the upper surface and the lower surface of the first and the second supporting plates 2₁, 2₂, first threaded holes Sh₁ to penetrate through in the Y-axis direction are bored. Further, in the wall surface portion of the second chamber parts 4₁, 4₂ that correspond to the first threaded holes Sh₁ when the first and the second supporting plates 21, 22 are mounted on the openings 11, 12 of the second chamber parts 4₁, 4₂, second threaded holes Sh₂ are bored. Then, in a state of mounting the first and the second supporting plates 2₁, 2₂ on the openings 11, 12 of the second chamber parts 4₁, 4₂, the fastening bolts Fb₁, Fb₂ are screwed into each of the first and the second threaded holes Sh₁, Sh₂. As a result, in a state in which the vacuum seals (not illustrated) are in pressurized contact with the wall surface part positioned around the openings 11, 12 of the second chamber parts 4₁, 4₂, and with the first and the second supporting plates 2₁, 2₂, the second chamber parts 4₁, 4₂ can be fixed to the first and the second supporting plates 2₁, 2₂.

On the side walls which are positioned in the X-axis direction of the first chamber part 1 and the second chamber part 4₁, 4₂ in a manner to lie opposite to each other, there are respectively formed through holes 13a, 13b, 41, 42 which allow for the sheet-shaped substrate Sw to pass therethrough. In a clearance between both the side walls of the first chamber parts 1 and the second chamber parts 4₁, 4₂, load lock valves 5 are disposed in a manner to cover such a portion of the substrate Sw as will pass through this clearance. It is thus so arranged: that the sheet-shaped substrate Sw can be transferred in the vacuum atmosphere throughout and also; that the vacuum processing chamber Ms can be isolated from both the transfer chambers Ts1, Ts2. By the way, as the load lock valve 5 that is utilized in this kind of vacuum processing apparatus, publicly known art may be utilized. Therefore, detailed description thereof will be omitted here.

The first transfer chamber Ts1 that is positioned in one X-axis direction (left side in FIG. 1) is provided with a feed roller Wr around which the sheet-shaped substrate Sw before film formation is wound. A rotary shaft Wa of the feed roller Wr is rotatably supported by a second supporting plate 2₂ and is driven for rotation by a motor M1 which is disposed outside the vacuum chamber Vc. The second transfer chamber Ts2 is provided with a take-up roller Ur which takes up a substrate Sw on which a thin firm has been formed. A rotary shaft Ua of the take-up roller Ur is also rotatably supported by the second supporting plate 2₃ and is driven for rotation by a motor M2 which is disposed outside the vacuum chamber Vc. By the way, in each of the first and the second transfer chambers Ts1, Ts2, there are disposed guide rollers Gr, as required, serving as transfer rollers for guiding the transfer of the sheet-shaped substrate Sw. The rotary shafts Ga of the guide rollers Gr are also rotatably supported respectively on the second supporting plate 2₂.

The vacuum processing chamber Ms is provided with guide rollers Gr and a can roller Cr. It is thus so arranged that the sheet-shaped substrate Sw gets cooled while it is transferred along the periphery of the can roller Cr. The rotary shafts Ga, Ca of the guide rollers Gr and of the can roller Cr are also rotatably supported by the second supporting plate 2₂. The can roller Cr is arranged to be driven for rotation by a motor M3 that is disposed out of the vacuum chamber Vc. Then, inside the vacuum processing chamber Ms there are disposed two evaporation sources ES₁, ES₂ according to this embodiment, for performing film forming processing on both surfaces of the substrate Sw.

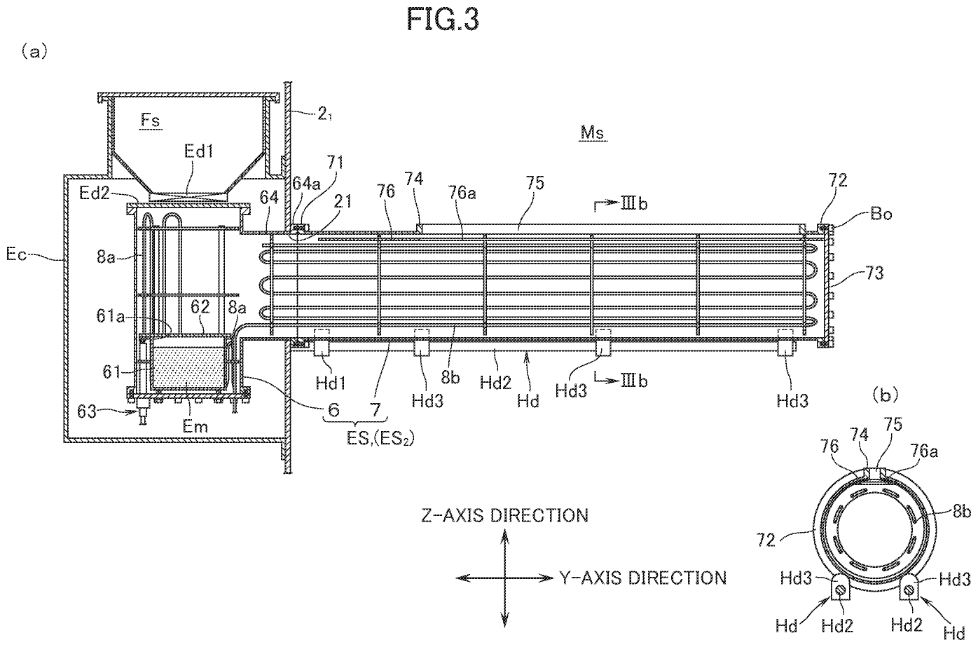

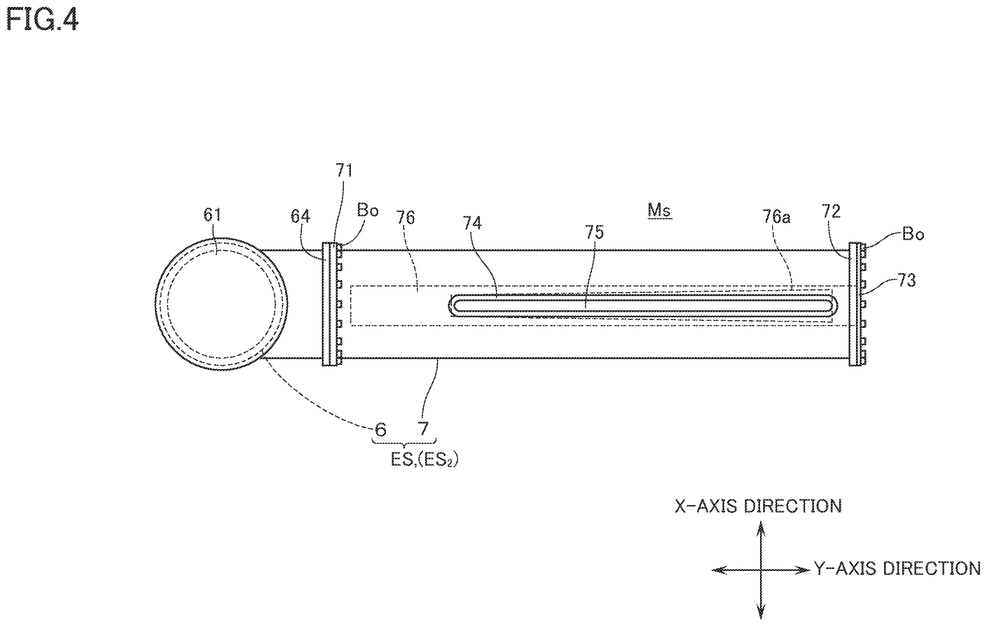

With reference also to FIGS. 3 and 4, each of the evaporation sources ES₁,ES₂ has the same arrangement and is provided with a main cylindrical body 6 and a secondary cylindrical body 7. In this case, on an outside side surface in the Y-axis direction of the first supporting plate 2₁, there are disposed, in communication with one another, extension chambers Ec depending the position and number of disposing each of the evaporation sources ES₁, ES₂. On an upper part of the extension chamber Ec there is disposed a material filling chamber Fs having an open/close door Ed1 which is positioned at a lower part in the Z-axis direction. Although not described by particularly illustrating, the material filling chamber Fs has connected thereto a vacuum pump unit made up of a turbo molecular pump, a rotary pump, and the like through an exhaust pipe, and a vent pipe so that a vacuum atmosphere independent of the extension chamber Ec (that is in communication with the vacuum chamber Vc) can be formed (despite the above comment, the extension chamber Ec may also be arranged so as to be evacuated by the vacuum pump that is independent of the vacuum chamber Vc). In case the evaporation material Em is filled in a crucible part 61 that will be described hereinafter, the evaporation material Em is charged into the material filling chamber Fs in a state in which the material filling chamber Fs is left open to the atmosphere. Thereafter, the material filling chamber Fs is exhausted into vacuum and, when the inside thereof has reached a predetermined pressure, the open/close door Ed1 and an open/close door Ed2 for the main cylindrical body 6 (to be described hereinafter) are open to atmosphere. According to these operations, the evaporation material Em can be filled in a crucible part 61 which is to be described hereinafter, without opening the vacuum chamber Vc to atmosphere. By the way, it may also be so arranged that a material automatic transfer mechanism having the known construction may be disposed so as to fill the evaporation material Em. Then, inside the extension chamber Ec there is disposed the main cylindrical body 6 of each of the evaporation sources ES₁, ES₂, wherein the main cylindrical body 6 has a cylindrical contour and disposed in a posture in which the longitudinal direction of the main cylindrical body coincides with a vertical direction.

The main cylindrical body 6 has a bottomed cylindrical profile and at the bottom in the Z-axis direction thereof there is disposed a crucible part 61 in which is filled a solid evaporation material Em in a predetermined filling factor. The evaporation material Em is appropriately selected depending on the composition of the thin film that is going to be formed (evaporated) on the sheet-shaped substrate Sw. For example, there will be used metallic materials such as aluminum, lithium, indium, and their alloys or organic materials. On an upper-surface opening of the main cylindrical body 6 there is disposed the open/close door Ed2 and, when the open/close door Ed2 of the known structure is closed, the inside of the main cylinder 6 is arranged to be hermetically closed. In addition, the crucible part 61 is provided with a lid body 62 which freely opens or closes the upper-surface opening 61a. In this case, inside the main cylindrical body 6 an actuator 63 is disposed. By this actuator 63 the main cylindrical body 6 can be swung between an erected posture in which the lid body 62 is erected in the Z-axis direction and a horizontal posture (see FIG. 3) in which the upper-surface opening 61 is blocked and, at the same time, during the horizontal posture, the lid body 62 is urged against the crucible part 61 so that the contact pressure can be secured between the lid body 62 and the crucible part 61 (in other words, as described hereinafter, due to the sublimation or evaporation of the evaporation material Em, even at the time when the internal pressure has risen, the conductance can be secured between the lid body 62 and the crucible part 61 so that an unfavorable leakage of the evaporation material Em into the main cylindrical body 6 does not occur). By the way, since the known art can be utilized as this kind of actuator 63, further description thereof will be omitted.

On an outer circumference of the main cylindrical body 6 a branched tube body 64 of cylinder elongated in the Y-axis direction is disposed in a protruded manner such that, and the branched tube body 64 has a mounting flanges 64a on the end thereof. In a state in which the open/close door Ed2 is closed, the inner atmosphere of the main cylindrical body 6 is such that only the branched tube body 64 is made to be an object of communication. The branched tube body 64 is inserted into a through hole 21 provided in the first supporting plate 2₁ and the front end thereof is protruded up to the vacuum processing chamber Ms. The height position in the Z-axis direction of the branched tube body 64 is set to be positioned at least above the upper layer portion of the evaporation material Em to be filled inside the crucible part 61. The main cylindrical body 6 is provided inside thereof with a sheath heater (heating means) 8a so that, by electrically energizing the sheath heater 8a from an electric power source (not illustrated), not only the evaporation material Em in the crucible part 61 but also the inner surface of the main cylindrical body 6 and the lid body 62 can be heated throughout the entirety thereof.

The secondary cylindrical body 7 positioned inside the vacuum processing chamber Ms has a cylindrical profile which is provided, on both ends thereof, with mounting flanges 71, 72 corresponding to the mounting flange 64a and is sized to be larger than the width of the sheet-shaped substrate Sw. Then, in a state in which the mounting flange 64a and the mounting flange 71 on one side of the Y-axis direction are brought into contact with each other, both members are tightened with bolts Bo as tightening means. In this manner, the secondary cylindrical body 7 is detachably mounted on the main cylindrical body 6 and is positionally supported by the holders Hd. The holders Hd are provided with base end blocks Hd1 which are fixed to the inner wall of the first supporting plate 2₁, and two supporting columns Hd2 which are supported in cantilever by the base end blocks Hd1 so as to be elongated in the Y-axis direction. Each of the supporting columns Hd2 is provided with supporting blocks Hd3 at a predetermined distance in the Y-axis direction. The supporting blocks Hd3 are constituted to support the secondary cylindrical body 7 in point-contact (i.e., although fixed in position, not to receive surface pressure other than the self-weight) so that heat transfer by contact becomes minimum (see FIG. 3(b)). It is to be noted here that the above-mentioned point contact means a design thought in that the supporting area shall be limited to such a degree as to be free from giving rise to a permanent set by surface pressure due to a self-weight. Ordinarily, a contact pressure is estimated with a reasonable safety factor, a contact area is determined, and the thermal resistance is maximized. In a sense to intend an increase in resistance, the supporting block may be made of a ceramic with a low conductivity. For example, in place of a metal, by using general-purpose screws made of aluminum oxide as supporting blocks, the thermal conductivity can further be lowered. In addition, it is possible to decrease the thermal conduction. Further, the main cylindrical body 6 may preferably be provided with reflectors (not illustrated) around the secondary cylindrical body 7 so that the resistance value is increased not only relative to the contact heat transmission but also the radiation heat transmission, thereby employing an arrangement of lower heat transmission.

The method of fixedly supporting the secondary cylindrical body 7 to the main cylindrical body 6 shall not be limited to the above-mentioned example. For example, clamps and the like may similarly be employed. At this time, if the secondary cylindrical body 7 can be fixedly supported by rotating the secondary cylindrical body 7 by a predetermined angle about its hole axis (coinciding with the Y-axis), it becomes possible to arbitrarily shift the phase of a discharge opening 75 which is described hereinafter. In this embodiment, the evaporation source ES₁ which is positioned on the side of the first transfer chamber Ts1 is in a posture in which the discharge opening 75 looks upward in the Z-axis direction, and in the evaporation source ES₂ which is positioned on the side of the second transfer chamber Ts2 is in a posture in which in which the discharge opening 75 looks downward in the Z-axis direction (see FIG. 1). The mounting flange 72 on the other side in the Y-axis direction has disposed therein a lid plate 73 which closes the inside of the secondary cylindrical body 7. This lid plate 73 is arranged to hold a distribution plate 76 which is referred to hereinafter. At this time, the inside atmosphere of the main cylindrical body 6 and the secondary cylindrical body 7 is in communication with each other. Further, the state is that the communication port between the inside atmosphere and the outside does not exist except for the discharge opening 75 which is described hereinafter. In addition, in a state in which the lid plate 73 and the mounting flange 72 on the other side in the Y-axis direction are brought into contact with each other, both the members are fastened by bolts Bo as the fastening means. The lid plate 73 is thus arranged to be detachably mounted on the flange.

The secondary cylindrical body 7 is provided on an outer periphery thereof with a projected strip 74 having a profile of a race track shape, the projected strip being separated in the Y-axis direction away from one of the mounting flange 71. Also, in a manner to be enclosed by the projected strip 74 a slit-shaped discharge opening 75 is disposed in a manner to be elongated in the Y-axis direction. In a state in which the evaporation sources ES₁, ES₂ have been mounted in position, the discharge openings 75 are arranged to lie opposite to such portions of the sheet-shaped substrate Sw as are transferred inside the vacuum processing chamber Ms. Inside the secondary cylindrical body 7 there is also disposed, by insertion, a distribution plate 76. This distribution plate 76 has distribution holes 76a through which the sublimated or vaporized evaporation material Em passes when the evaporation material is introduced into the discharge opening 75. As shown in FIG. 4, the distribution plate 76 has a length to extend along substantially the entire length in the Y-axis direction of the secondary cylindrical body 7 by bridging over the discharge opening 75, and a width (length in the X-axis direction) larger than the discharge opening 75. The distribution hole 76a is arranged by a single slot located right below the discharge opening 75 and is disposed from the main cylindrical body 6 side toward the other side in the Y-axis direction so that the opening area continuously increases. The amount of increase in the opening area is appropriately set considering the film thickness distribution in the Y-axis direction (in the width direction of the sheet-shaped substrate Sw) when a film has been formed on the sheet-shaped substrate Sw.

In the above-mentioned embodiment, a description was made of an example in which a distribution hole 76a is made up of a single slot. However, as long as the film thickness distribution can be made substantially uniform when a film has been formed on the sheet-shaped substrate Sw, there shall be no need of limiting to the example. For example, it is possible to make up by disposing a plurality of holes of different areas. Further, in the above-mentioned embodiment, a description was made of an example of using the distribution plate 76, but an arrangement may be made that the discharge opening 75 is disposed from the side of the main cylindrical body 6 so as to continuously increase the opening area, thereby omitting the distribution plate 76. Further, an arrangement has been made that, inside the secondary cylindrical body 7, a sheath heater 8b (heat generating body) as the heating means is disposed. By energizing electricity to the sheath heater 8b from a power supply (not illustrated), heating can be made to the inner surface of the secondary cylindrical body 7 or the surface of the distribution plate 76 over the entire surface thereof. In this embodiment, the sheath heater 8b is disposed inside the secondary cylindrical body 7. This sheath heater may be omitted as long as the main cylindrical body 6 and the secondary cylindrical body 7 can be sufficiently heated by radiation and heat transmission when the evaporation material Em in the crucible part 61 is heated.

In case a film is formed on both surfaces of the sheet-shaped substrate Sw while the sheet-shaped substrate Sw is made to travel inside the above-mentioned vacuum evaporation apparatus DM, first, in a state in which preparation is made of the material in the material filling chamber Fs as described above, the open/close doors Ed1, Ed2 are opened, and the lid body 62 is made into an erected posture by the actuator 63, a predetermined filling ratio of evaporation material Em is charged in the crucible part 61 at a predetermined filling factor. At this time, in one of the transfer chambers Tc1 of the vacuum chamber Vc, a sheet-shaped substrate Sw: gets wound around the feed roller Wr; and the front end portion thereof get wound around each of the guide rollers Gr and the can roller Cr respectively in the vacuum processing chamber Ms; and is taken up by the take-up roller Ur through guide rollers Gr. In this state, the vacuum processing chamber Ms and both the transfer chambers Ts1, Ts2 will have been in a stand-by state of having been evacuated down to a predetermined pressure.

After having filled the evaporation material Em, the lid body 62 is made into the horizontal posture and also the open/close doors Ed1, Ed2 are closed respectively. Then, once the extension chamber Ec has reached the predetermined pressure, the sheath heaters 8a, 8b are energized with electricity so as to heat the main cylindrical body 6 and the secondary cylindrical body 7 of each of the evaporation sources ES₁, ES₂ inclusive of the crucible part 61. Here, in case the evaporation material Em is a volatile material, when the evaporation material Em has reached the predetermined temperature, the evaporation material Em in the crucible part 61 gets liquefied. The evaporation material Em filled in the crucible part 61 will start liquefied from the upper-layer portion according to the vapor-pressure curve peculiar to the evaporation material Em in question. At this time, the pressure in the crucible part 61 (partial pressure of the evaporation material Em) will rise to the vapor pressure corresponding to the predetermined temperature and then shifts to the thermal equilibrium state in which vaporization will be restrained due to vapor pressure rate-limiting. The evaporation material Em filled in the crucible part 61 will be liquefied (energize current through the sheath heater 8a (heater output) will be stabilized)).

Then, the motors M1 through M3 are driven for rotation to thereby cause the sheet-shaped substrate Sw to travel at a set speed and also the lid body 62 is made to an erected posture by an actuator 63. Then, in order for the difference in partial pressure to attain an equilibrium state, the difference being of the partial pressure that is present in the vacuum processing chamber Ms under vacuum atmosphere, the vaporized evaporation material Em will be shifted (distributed) to the secondary cylindrical body 7 through the main cylindrical body 6 while maintaining the vapor pressure, and is introduced by the distribution plate 76 to the discharge opening 75, and is discharged into the vacuum atmosphere. At this time, in the evaporation source ES₁ the discharge opening 75 looks upward, a film is formed on one surface of the sheet-shaped substrate Sw in a so-called evaporation up (“depo-up”) style. While getting transferred around the periphery of the can roller Cr, the sheet-shaped substrate Sw is once cooled. Subsequently in the evaporation source ES₂ since the discharge opening 75 looks downward, a film is formed on the other surface of the sheet-shaped substrate Sw in a so-called evaporation down (“depo-down”) style. The sheet-shaped substrate Sw having formed films on both surfaces thereof is transferred to the other transfer chamber Ts2 and is taken up by the take-up roller Ur. After having opened the other transfer chamber Tc2 to the atmosphere, the substrate Sw on which the processing of film formation has been finished is recovered.

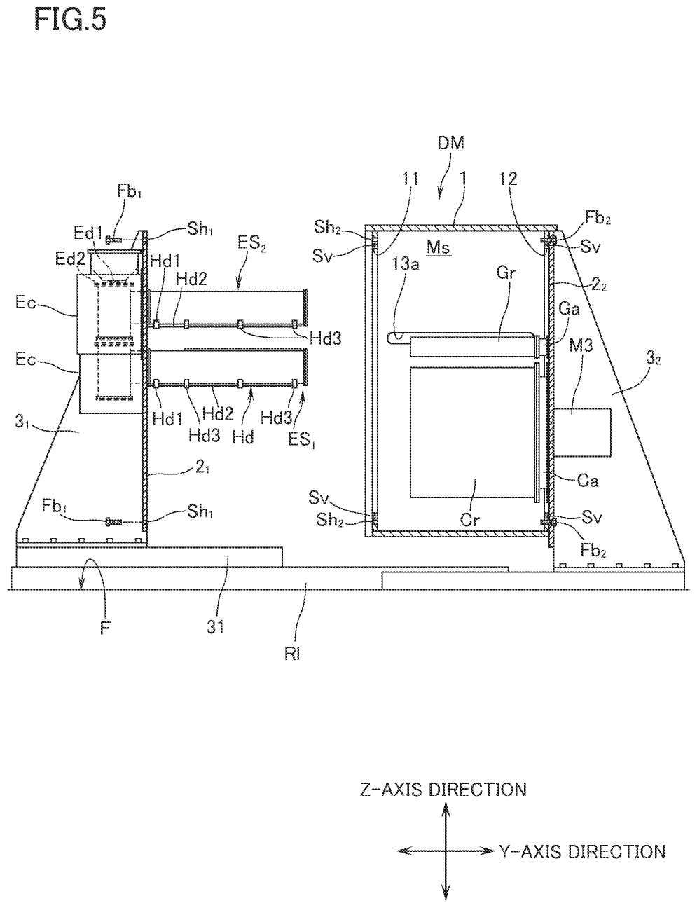

After having recovered the sheet-shaped substrate Sw on which the processing of film formation has been finished (i.e., after completion of production), in case the worker performs maintenance work, in preparation for the next production, such as replacement of the distribution plate 76 accompanied by the change in kind of the evaporation material Em, cleaning of the secondary cylindrical body 7, replacement of the sheath heaters 8a, 8b and the like, all of the fastening bolts Fb₁ which tighten the first supporting plate 2₁ and the first chamber together. Then, after having left open to atmosphere the vacuum chamber Vc, the supporting frame 3₁ is moved through the slider 31 in one X-axis direction (see FIG. 5). According to these operations, the secondary cylindrical body 7 can be pulled out to a wide space which is apart from the vacuum processing chamber Ms, thereby improving the workability of maintenance work.

According to the above, there has been employed an arrangement: in which the portion (main cylindrical body 6) of heating the evaporation material Em for sublimation or evaporation, and the portion of transferring and discharging the sublimated or vaporized evaporation material Em (secondary cylindrical body 7) are separated (i.e., making the evaporation sources ES₁, ES₂ to be of gaseous transfer (diffusion) style); and also in which the phase of the discharge opening 75 provided in the secondary cylindrical body 7 can be shifted. Therefore, the evaporation direction relative to the sheet-shaped substrate Sw can be set at will such as so-called evaporation-up style or evaporation-down style, thereby bringing out superiority in uses. Further, since the secondary cylindrical body 7 is arranged to have inserted thereinto the distribution plate 76 that is fixed to the lid plate 73, by appropriately setting the shape, opening area, and the like of the distribution holes 76a to be formed in the distribution plate 76, it becomes possible to eject the evaporation material Em with good uniformity out of the slit-shaped discharge opening 75. In addition, in case, for example, the evaporation material Em changes in kind, the distribution plate 76 may be replaced for another having different shape of distribution holes 76a and different opening area, thereby bringing about superiority in uses.

Further, since the heat generating body (heat generating source) 8b is present inside the secondary cylindrical body 7, as compared with the heat transmission system via the wall surfaces of the secondary cylindrical body 7 as noted above, the present invention can constitute an industrially advantageous constitution with improved heat efficiency. Aside from the above, by keeping the inner wall of the secondary cylindrical body 7 and parts such as the distribution plate 76 and the like provided inside thereof can be kept heated at a higher temperature than the sublimation temperature or evaporation temperature of the evaporation material Em, evaporation of the evaporation material Em that has been transferred to the secondary cylindrical body 7 can be prevented from adhesion (or deposition) (so-called self cleaning). Still furthermore, the vapor pressure of the evaporation material Em inside the main cylindrical body 6 and the secondary cylindrical body 7 can advantageously be attempted to be stabilized. Still furthermore, at the time of re-filling of the evaporation material Em, the work (operation) such as of returning the vacuum chamber Vc back to atmospheric pressure becomes needless, thereby bringing about the improvement in the productivity. It is to be noted that, as the heat generating body 8b, the known art may be used other than the sheath heater.

Descriptions have so far been made of embodiments of this invention, but this invention shall not be limited to the above-mentioned embodiments. As far as the essence of this invention is not departed from, various modifications are possible. In the above-mentioned embodiments, the film-evaporation object was made to be a sheet-shaped substrate Sw, but the evaporation sources ES₁, ES₂ of this invention can also be used for the film formation on a rectangular substrate. At this time, depending on the posture of the substrate, the discharge opening 75 can take the posture of looking vertically upward, the discharge opening 75 can take the posture of looking at a horizontal direction, or the discharge opening 75 can take the posture of looking vertically downward. Despite the above, the crucible part 61 shall preferably keep the vertical posture in the Z-axis direction from the viewpoint of its physical characteristics. This is for the purpose of employing an arrangement of minimizing the variation in the charging efficiency and in the area at the gas-liquid interface of the evaporation material Em at the time of evaporation. Furthermore, at the time of forming a film on such a portion of the sheet-shaped substrate Sw as is wound around the can roller Cr (i.e., the portion being cooled), a Y-axis axial line of the secondary cylindrical body7 may be set on the X-Z plane and the discharge opening 75 may be rotated about the Y-axis so as to be in a position to lie opposite to the can roller Cr (in this case, the Z-axis axial line shall be kept to maintain the vertical). In case the rotary axial line of the can roller Cr is not horizontal (the axis of rotation is not vertical to the X-Z plane), the axial line of the secondary cylindrical body 7 may be set in an inclined manner so that the discharge opening 75 lies along the can roller Cr. On the other hand, in case cooling of the sheet-shaped substrate Sw is required, in the vacuum evaporation apparatus DM as shown in FIG. 1, a cooling roller and a cooling panel (not illustrated) may be disposed, on such a side of the sheet-shaped substrate Sw as is opposite to the surface thereof on which a film is formed, in a manner to lie opposite to each of the discharge openings 75 of the evaporation sources ES₁, ES₂.

### EXPLANATION OF MARKS

DM vacuum evaporation apparatus

Ec extension chamber

Em evaporation material

ES₁, ES₂ evaporation source

Sw sheet-shaped substrate (film formation object)

Vc vacuum chamber

6 main cylindrical body

61 crucible part

61a upper-surface opening

62 lid body

7 secondary cylindrical body

75 discharge opening

76 distribution plate

76a distribution hole

8a sheath heater (heating means)

8b sheath heater (heat generating body)

1. An evaporation source for a vacuum evaporation apparatus which performs vacuum evaporation on a film formation object in a vacuum chamber, the evaporation source comprising:
a main cylindrical body disposed in a posture in which a longitudinal direction thereof coincides with a vertical direction, the main cylindrical body having a crucible part to be filled with an evaporation material; a secondary cylindrical body protruded from such a part of the main cylindrical body as is positioned above the evaporation material filled in the crucible part, the secondary cylindrical body having a discharge opening; and a heating means capable of heating at least the evaporation material that is filled in the crucible part,
the secondary cylindrical body being detachably mountable on the main cylindrical body while shifting a phase of the discharge opening,
a lid body being disposed to block an upper-surface opening of the crucible in a manner to open or close the opening,
wherein the evaporation source is so arranged: that, in a state in which the upper-surface opening of the crucible part is blocked by the lid body in a vacuum atmosphere, the evaporation material in the crucible part is heated by the heating means so as to sublime or vaporize the evaporation material; and that, when the lid body is left open, the sublimated or evaporated evaporation material is transferred to the secondary cylindrical body while maintaining a vapor pressure thereof.

2. The evaporation source for a vacuum evaporation apparatus according to claim 1, wherein the discharge opening is constructed into a slit elongated in one direction and wherein a distribution plate is disposed by insertion into the secondary cylindrical body, the distribution plate having formed therethrough distribution holes for introducing, into the discharge opening, the sublimated or vaporized evaporation material transferred into the secondary cylindrical body.

3. The evaporation source for a vacuum evaporation apparatus according to claim 1, wherein the heating means further comprises a heat generating body disposed in the secondary cylindrical body.
